(19) United States
(12) Patent Application Publication
(10) Pub. No.: US 2012/0255599 A1
(43) Pub. Date: Oct. 11, 2012

(54) NANOCONE-BASED PHOTOVOLTAIC SOLAR CELLS

(75) Inventors: Jun Xu, Knoxville, TN (US); Sang Hyun Lee, Knoxville, TN (US); David Barton Smith, Oak Ridge, TN (US); Xiaoguang Zhang, Oak Ridge, TN (US); Chad E. Duty, Knoxville, TN (US)

(73) Assignee: UT-BATTELLE, LLC, Oak Ridge, TN (US)

(21) Appl. No.: 13/080,222

(22) Filed: Apr. 5, 2011

(51) Int. Cl. H01L 31/06; H01L 31/0336

(52) U.S. Cl. 136/255; 438/85; 438/95; 257/E31.005

(57) ABSTRACT

A photovoltaic structure including a nanocone-based three-dimensional interdigitated p-n junction is provided in the present invention. The three-dimensional p-n junction is at the interface between n-type oxide semiconductor nanocones and a p-type semiconductor material that functions as a matrix embedding the nanocones. The nanocone-based three-dimensional p-n junction allows efficient minority carriers being extracted from photo-absorber and crossing across the p-n junction, and generates completely-depleted regions throughout the nanocones and the matrix around the nanocones for efficient charge collection. Further, the bandgap energies of the p-doped semiconductor material can be tuned to match the solar light spectrum by mixing related elements. Further, the high temperature pulses can be used to remove defects in the junction interfaces and sintering nanoparticle matrix.

### STATEMENT REGARDING FEDERALLY SPONSORED RESEARCH OR DEVELOPMENT

This invention was made with government support under Contract No. DE-AC05-00OR22725 awarded by the U.S. Department of Energy. The government has certain rights in this invention.

### FIELD OF THE INVENTION

The present invention relates to a photovoltaic device, and particularly to a photovoltaic device including a nanocone structure, and methods of manufacturing the same.

### BACKGROUND OF THE INVENTION

Currently, all commercial photovoltaic structures employ planar structures. A conflict arises in controlling the thicknesses of these planar material layers. If the planar layers are thin, solar light cannot be completely absorbed by the layers. If the planar layers are thick, charge carriers generated by the photons cannot get collected because they are trapped by defects existed in these thick layers. Therefore photo-electrical conversion efficiency is limited for these planar solar cells.

### SUMMARY OF THE INVENTION

A photovoltaic structure including a nanocone-based three-dimensional interdigitated p-n junction is provided in the present invention. The three-dimensional p-n junction is at the interface between n-type oxide semiconductor nanocones and a p-type semiconductor material that functions as a matrix either partially or fully embedding the nanocones. The nanocone-based three-dimensional p-n junction allows efficient minority carriers crossing across the p-n junction, and generates completely-depleted regions throughout the nanocones and the matrix around the nanocones for efficient charge collection. Further, the band gap energies of the both n-type and p-type semiconductor materials can be tuned to match the solar light spectrum by mixing related elements.

Additionally, the present invention provides methods of synthesizing Zn₁₋ₓCdₓO nanocones on indium-tin-oxide and other solar-transparent substrates, methods of synthesizing CdTe and ZnTe p-type matrix between nanocones, and methods of minimizing interfacial defects using pulsed thermal processing (PTP). The value of x can be from 0 to 1, i.e., 0, 1, or any value therebetween.

The nanocone-based photovoltaic structure of the present invention can be formed by first growing an array of vertically aligned oxide semiconductor nanocones on a transparent conductive oxide (TCO) substrate in the ambient of a lateral growth control agent. The lateral growth control agent allows growth at the ledges located at the periphery of the uppermost surface of a oxide semiconductor frustum (a cone with its apex cut off by a plane parallel to its base) less than at the upper surface of the oxide semiconductor frustum, thereby providing a taper to the sidewalls of the oxide semiconductor frustum until the oxide semiconductor nanocones are completed. Vertical alignment of the nanocones is ensured by depositing aluminum-doped ZnO film prior to the nanocone synthesis. A p-type CdTe semiconductor material can be conformally deposited on the array of oxide semiconductor nanocones, and effectively activated by an anneal that can be performed in a CdCl₂ solution or in CdCl₂ vapor. The solar cell structure has a depletion zone that encompasses the entirety of the oxide semiconductor nanocones and the p-type semiconductor material embedding the oxide semiconductor nanocones. An electrical field distribution that is inherently generated by the oxide semiconductor nanocones facilitate (1) photon-generated minority charge carriers to cross over the p-n junction in both the embedding CdTe material and in the oxide semiconductor nanocones and (2) majority carriers, either originating from photo-generation or from the crossover, to move to their respective electrodes.

According to an aspect of the present invention, photovoltaic device includes a p-n junction between a plurality of nanocones having a doping of a first conductivity type and a doped semiconductor matrix contacting and at least partially embedding the plurality of nanocones and having a doping of a second conductivity type that is the opposite of the first conductivity type.

According to another aspect of the present invention, a method of forming a photovoltaic device is provided, which includes: forming a plurality of nanocones having a doping of a first conductivity type on a transparent conductive oxide (TCO) substrate; and forming a doped semiconductor matrix having a doping of a second conductivity type that is the opposite of the first conductivity type directly on the plurality of nanocones, wherein the plurality of nanocones become at least partially embedded in the doped semiconductor matrix, and a p-n junction is formed between the plurality of nanocones and the doped semiconductor matrix.

According to still another aspect of the present invention, a method of enhancing electrical characteristics of an interdigitated three-dimensional p-n junction, the method including: forming a plurality of nanocones having a doping of a first conductivity type on a transparent conductive oxide (TCO) substrate; forming a doped semiconductor matrix directly on the plurality of nanocones, wherein the doped semiconductor matrix has a doping of a second conductivity type that is the opposite of the first conductivity type, wherein an interdigitated three-dimensional p-n junction is formed between an interface between the doped semiconductor matrix and the plurality of nanocones; and applying at least one thermal pulse to the plurality of nanocones and the doped semiconductor matrix, wherein electrical characteristics of the interdigitated three-dimensional p-n junction include at least one of a decrease in interfacial defects between the doped semiconductor matrix and the plurality of nanocones and an increase in conductivity of the doped semiconductor matrix.

### BRIEF DESCRIPTION OF THE DRAWINGS

FIG. 1 is a schematic vertical cross-sectional view of an exemplary structure including a transparent substrate layer, a transparent conductive oxide layer, and a doped semiconducting zinc oxide buffer layer according to an embodiment of the present disclosure.

FIG. 2 is a schematic vertical cross-sectional view of the exemplary structure during formation of an array of oxide semiconductor nanocones according to an embodiment of the present disclosure.

FIG. 3 is a schematic vertical cross-sectional view of the exemplary structure after formation of an array of oxide semiconductor nanocones according to an embodiment of the present disclosure.

FIG. 4 is a scanning electron micrograph of a sample of an array of ZnO nanocones.

FIG. 5 shows X-ray spectra of an aluminum-doped zinc oxide buffer layer and zinc oxide nanocones.

FIG. 6 is a schematic vertical cross-sectional view of the exemplary structure after formation of a doped semiconductor layer and a conductive plate according to an embodiment of the present disclosure.

FIG. 7 is a schematic vertical cross-sectional view of a first variation of the exemplary structure that includes cavities between the doped semiconducting zinc oxide buffer layer and the doped semiconductor layer.

FIG. 8 is a schematic vertical cross-sectional view of a second variation of the exemplary structure that includes transparent polymers between the doped semiconducting zinc oxide buffer layer and the doped semiconductor layer.

FIG. 9 is a scanning electron micrograph of a sample of an array of n-type semiconducting zinc oxide nanocones after deposition of a thin layer of a p-type compound semiconductor material. In this case, the entire surface of the nanocones is covered by the semiconductor with opposite conducting carriers.

FIG. 10 shows a scanning electron micrograph of a sample of a photovoltaic structure including nanocones and a doped semiconductor matrix. In this case, the tip portion (partial surface) of the nanocones is covered by the semiconductor with opposite conducting carriers. (FIG. 10 should be replaced with a better picture)

FIG. 11 is a scanning electron micrograph of a surface of a CdTe layer in the sample of FIG. 10. (not closely relevant, should be removed)

FIG. 12 shows an X-ray spectrum of the CdTe layer in the sample of FIG. 10.

FIG. 13 is a J-V plot, i.e., a plot showing current density (current divided by illumination area) J versus voltage bias V applied between the front electrode and the back electrode, of an exemplary nanocone ZnO—CdTe solar cell according to an embodiment of the present disclosure and a reference ZnO—CdTe solar cell having planar layers.

### DETAILED DESCRIPTION OF THE INVENTION

As stated above, the present invention relates to a photovoltaic device including a nanocone structure, and methods of manufacturing the same, which are now described in detail with accompanying figures. It is noted that like and corresponding elements mentioned herein and illustrated in the drawings are referred to by like reference numerals. It is also noted that proportions of various elements in the accompanying figures are not drawn to scale to enable clear illustration of elements having smaller dimensions relative to other elements having larger dimensions.

As used herein, a “transparent conductive oxide (TCO) substrate” refers to any electrically conductive substrate that is transmissive, allowing solar radiation to pass through, while providing an electrode contact for a device thereupon.

As used herein, a “depleted region,” or a “depleted junction region” refers to a semiconductor region in which static electric field is present in the absence of illumination or an externally applied voltage bias.

As used herein, a “cone” refers to any element having a base and an apex and a strictly decreasing cross-sectional area (diameter) with distance from the base to the apex. Outer surfaces of a cone in a vertical cross-sectional profile through the axis of a cone may be linear, concave, or convex.

As used herein, a “nanocone” refers to any cone of which the maximum diameter is less than 1 micron and the maximum length is in 0.5 to 5 microns.

As used herein, a “nanocone structure” refers to any structure including at least one nanocone which is vertically aligned.

As used herein, a “nanowire” refers to a wire having a constant cross-sectional area (diameter) throughout.

As used herein, a structure is “interdigitated” if each of two components (for example, an n-type region and a p-type region) of the structure has portions that protrude into the other component.

A three-dimensional interdigitated heterojunction is formed between an n-type oxide semiconductor material in nanocone shapes and a p-type semiconductor material surrounding the nanocones either partially or fully. Charge transport efficiency within the nanocones and the p-type semiconductor material matrix surrounding the nanocones is enhanced. Further, the band gap energies of the heterojunction semiconductor materials can be tuned to match the solar light spectrum. Pulsed laser deposition (PLD) of compound semiconductor material can be employed to deposit the p-type semiconductor material which fully covers nanocone surface. Closed circle sublimation of CdTe can be employed to deposit the p-type semiconductor material which partially covers nanocone surface. Either spin-coating or dip-coating of p-type nanoparticle solution on nanocone surface, followed by annealing and sintering, can be employed to deposit the p-type material. Further, pulsed thermal processing (PTP) can enhance the crystal structure of the deposited p-type semiconductor material. A nano-architecture photovoltaic cell incorporating the nanocones can be constructed.

In a non-limiting illustrative embodiment, n-type ZnO and p-type ZnTe or CdTe can be employed to construct a nanostructure, in which nanocones including n-type ZnO are laterally surrounded by, and are eventually embedded within the p-type ZnTe matrix or the p-type CdTe matrix.

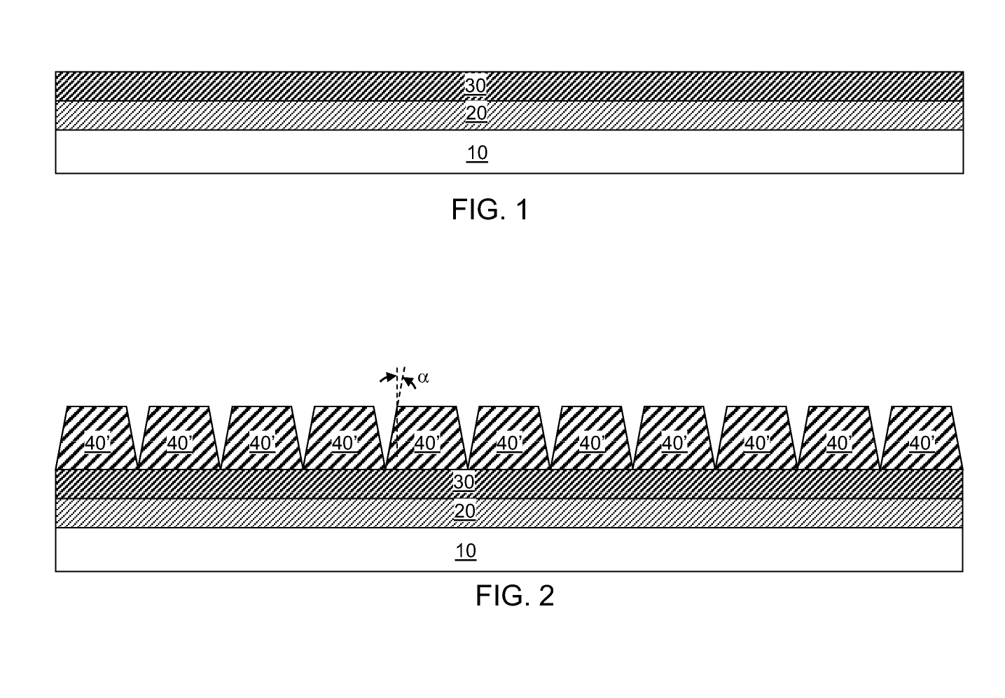

Referring to FIG. 1, an exemplary structure according to an embodiment of the present disclosure includes a transparent substrate layer 10, which includes an optically transparent material such as glass or sapphire. The thickness of the transparent substrate layer can be, for example, from 0.5 mm to 2 mm, although lesser and greater thicknesses can also be employed.

A transparent conductive oxide layer 20 is deposited on the transparent substrate layer 10 unless the transparent substrate layer 10 already includes a transparent conductive oxide material. While the transparent conductive oxide layer 20 can include a planar top surface as illustrated in FIG. 1, embodiments can be implemented in which the transparent substrate layer 10 and the transparent conductive oxide layer 20 have a non-zero curvature on their surfaces. The thickness of the transparent conductive oxide can be from 50 nm to 1,000 nm, and typically from 100 nm to 300 nm, although lesser and greater thicknesses can also be employed. The transparent conductive oxide layer 20 can be deposited by any method known in the art including simultaneous vacuum evaporation and sputtering. The transparent conductive electrode layer 20 functions as a front charge collection electrode, which is placed facing solar light during operation. In a non-limiting illustrative embodiment, the transparent conductive oxide layer 20 can include indium tin oxide. The transparent conductive oxide layer 20 and the transparent substrate layer 10 collectively constitute a transparent conductive oxide (TCO) substrate in which an electrode contact is provided by the transparent conductive oxide layer 20, and the transparent conductive oxide layer 20 and the transparent substrate layer 10 pass through solar radiation.

A doped conductive oxide buffer layer 30 is formed on the top surface of the transparent conductive oxide layer 20. The doped conductive oxide buffer layer 30 can be deposited, for example, by sputtering and/or vacuum evaporation. The thickness of the doped conductive oxide buffer layer 30 can be from 20 nm to 500 nm, and typically from 50 nm to 200 nm, although lesser and greater thicknesses can also be employed. In a non-limiting illustrative embodiment, the doped conductive oxide buffer layer 30 can be an n-doped zinc oxide layer. For example, an aluminum-doped zinc oxide layer is an n-doped zinc oxide layer. Typical concentration of aluminum in an aluminum-doped zinc oxide layer can be less than 0.1% in weight percentage.

The doped conductive oxide buffer layer 30 functions as an alignment-control buffer layer for nanocones to be subsequently formed thereupon. Specifically, the top surface of the doped conductive oxide buffer layer 30 is the surface to which the base of each nanocone to be subsequently formed is aligned to. Further, the growth direction of the nanocones is perpendicular to the local plane of the top surface of the doped conductive oxide buffer layer 30. The doped conductive oxide buffer layer 30 has the same type of conductivity as nanocones to be subsequently grown thereupon. If n-type for ZnO nanocones are subsequently grown, the doped conductive oxide buffer layer 30 has a doping of n-type. Embodiments are also contemplated herein in which p-type doping is employed.

While the doped conductive oxide buffer layer 30 can include a planar top surface as illustrated in FIG. 1, embodiments can be implemented in which the top surface of the doped conductive oxide buffer layer 30 has a non-zero curvature. In other words, the top surface of the doped conductive oxide buffer layer 30 can be only locally planar, thereby enabling definition of a two-dimensional plane that is tangential to the top surface of the doped conductive oxide buffer layer 30 at each point on the top surface of the doped conductive oxide buffer layer 30. Thus, the doped conductive oxide buffer layer 30 can be locally planar, and may, or may not, have a global curvature.

The local plane that tangentially contacts the top surface of the doped conductive oxide buffer layer 30 is herein referred to as a first plane. When the top surface of the doped conductive oxide buffer layer 30 is planar as illustrated in FIG. 1, the first plane coincides with the top surface of the doped conductive oxide buffer layer 30. The crystallographic orientations of the doped conductive oxide buffer layer 30 can be predominantly aligned to the direction perpendicular to the top surface of the doped conductive oxide buffer layer 30 in each region of the doped conductive oxide buffer layer 30. Thus, for any given first plane, the crystallographic orientations of the doped conductive oxide buffer layer 30 in a region contacting the first plane can be predominantly aligned to the direction perpendicular to the first plane. For any given region of the doped conductive oxide buffer layer 30, the corresponding geometric plane of the first plane is herein referred to as a horizontal plane, and the direction perpendicular to the first plane is herein referred to as a vertical direction. In a non-limiting embodiment, a major crystallographic orientation of the material of the doped conductive oxide buffer layer 30 can be aligned to the vertical direction. For example, if the doped conductive oxide buffer layer 30 includes an aluminum-doped zinc oxide material, the (0001) orientation of the aluminum-doped zinc oxide material can be aligned to the vertical direction.

Referring to FIG. 2, a conductive oxide material is grown on the top surface of the doped conductive oxide buffer layer 30. The conductive oxide material can be deposited, for example, concurrently or alternately supplying precursor materials for the conductive oxide material. For example, the conductive oxide material can be deposited by thermal vapor deposition of at least one constituent of the conductive oxide material.

In a non-limiting example, if the conductive oxide material is zinc oxide, zinc can be evaporated in an oxygen-containing ambient so that zinc oxide is formed. In another non-limiting example, if the conductive oxide material is ZnₓCd₁₋ₓO, zinc and cadmium can be evaporated simultaneously or alternately in an oxygen-containing ambient so that ZnₓCd₁₋ₓO can be formed. The value of x is greater than 0.8 and is less than 1.0. The partial pressure of oxygen can be from 10 mTorr to 100 Torr, and typically from 100 mTorr to 10 Torr, although lesser and greater oxygen partial pressures can also be employed. Optionally, an inert gas such as argon can be present in the ambient. The growth temperature for the conductive oxide material can be, for example, from 70° C. to 450° C., although lower and higher growth temperatures can also be employed.

The growth of the conductive oxide material proceeds in a manner that ultimately results in formation of a plurality of nanocones having bases that contact the top surface of the doped conductive oxide buffer layer 30. The growth of the plurality of nanocones is effected by a vertical growth of a plurality of frustums 40′ having a base that contacts the top surface of the doped conductive oxide buffer layer 30, i.e., located at the first plane, and a planar top surface that is parallel to the first plane and continues to move away from the first plane during the growth of the plurality of the frustums 40′. The planar top surface of each frustum 40′ is a terrace.

The angle α of the side surfaces of the plurality of frustums 40′, as measured from the vertical direction, is a non-zero positive number, and can range from 0.1 degree to 60 degrees, and typically from 10 degrees to 25 degrees, although lesser and greater angles can also be employed. Thus, the area of the terrace in each frustum 40′ decreases as the growth of the conductive oxide material proceeds and the terrace moves farther away from the top surface of the doped conductive oxide buffer layer 30, i.e., from the first plane.

The mechanism for the reduction in the area of the terrace with the growth of the plurality of frustum 40′ is provided by a differential growth rate of the conductive oxide material between growth on the terrace and growth at side surfaces of the plurality of frustums 40′. Specifically, the growth of the plurality of frustums 40′ proceeds in an ambient including a lateral growth control agent that suppresses growth on the side surfaces and edges forming the periphery of the terraces of the frustums 40′. The lateral growth control agent can be provided in gaseous form. In a non-limiting embodiment, the lateral growth control agent can be carbon dioxide or carbon monoxide in gaseous form provided in the ambient. The partial pressure of the carbon dioxide or carbon monoxide can be from 0.1 mTorr to 1 Torr, and typically from 1 mTorr to 100 mTorr, although lesser and greater partial pressures of carbon dioxide or carbon monoxide can also be employed. In general, the non-zero angle α tends to increase with the partial pressure of the lateral growth control agent.

Because the deposition on the edges of the terraces proceeds at a slower rate than the deposition on the terraces themselves, the vertical growth within the edges of each terrace proceeds faster than vertical growth at the edges. Thus, side surfaces of the plurality of frustums 40′ continue to maintain a non-zero angle α from the vertical direction, and the area of the terraces continues to shrink as the vertical distance from the top surface of the doped conductive oxide buffer layer 30 increases with the vertical growth of the plurality of frustums 40′. The non-zero angle α may remain constant throughout the growth of the plurality of frustums 40′ by maintaining the same growth environment until the plurality of frustums 40′ grows into a plurality of nanocones 40 as illustrated in FIG. 2, or may be changed intentionally or unintentionally by variations of the process parameters, e.g., the growth temperature or the concentration of lateral growth control agent, during the growth of the plurality of frustums 40′.

Further, the growth of the plurality of frustums 40′ can proceed by selective deposition of the conductive oxide material on the terraces of the plurality of frustums 40′ at the top surface of each frustum 40′, while the conductive oxide material is not deposited on the side surfaces of the plurality of frustums 40′. The side surfaces of a frustum 40′ refer to all surfaces of the frustum 40′ other than the surface of the base at the bottom and the surface of the terrace at the top.

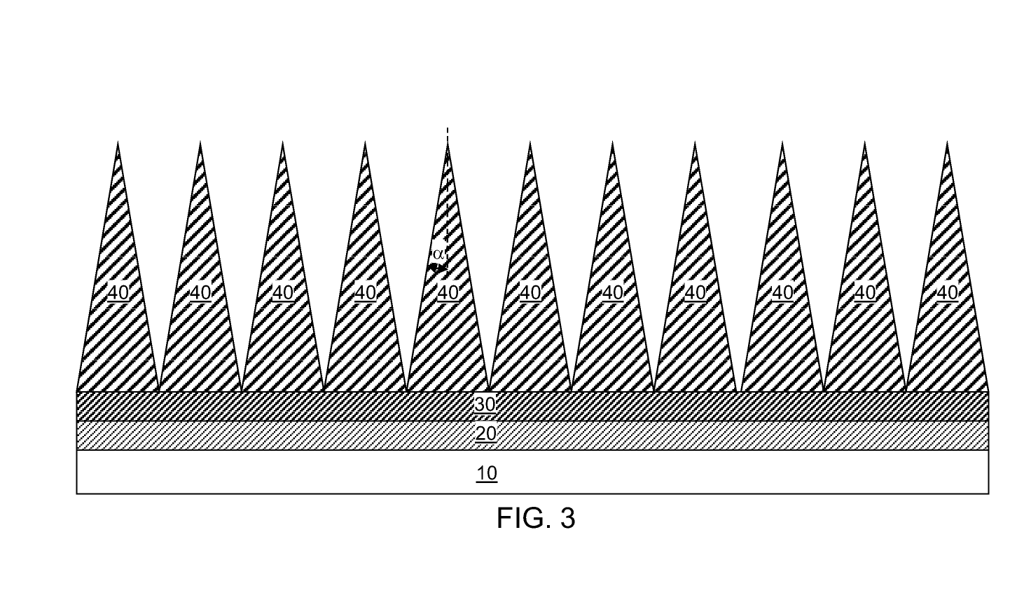

Referring to FIG. 3, a plurality of nanocones 40 formed by continuing the process employed to form the plurality of frustums 40′ until the area of the terraces shrink to zero, thereby converting the plurality of frustums 40′ into the plurality of nanocones 40. With the disappearance of terraces on which to continue deposition of the conductive oxide material, the growth on the plurality of nanocones 40 stops. Thus, the process of formation of the plurality of nanocones 40 is self-limiting, and does not proceed once the plurality of nanocones 40 is formed.

The plurality of nanocones 40 has an n-type doping or a p-type doping. The conductivity type of the doping of the plurality of nanocones 40 is herein referred to as a first conductivity type. The first conductivity type is the same as the type of doping that the doped conductive oxide buffer layer 30. In other words, both the doped conductive oxide buffer layer 30 and the plurality of nanocones 40 have a doping of the first conductivity type. Thus, if the doped conductive oxide buffer layer 30 has n-type doping, the plurality of nanocones 40 also has n-type doping, and if the doped conductive oxide buffer layer 30 has p-type doping, the plurality of nanocones 40 also has p-type doping.

Typically, the base of each of the plurality of nanocones 40 has a maximum dimension that is not greater than 500 nm, and each of the plurality of nanocones 40 has a height from 250 nm to 5,000 nm. In many cases, the plurality of nanocones 40 is a plurality of conical nanocones, i.e., nanocones that have horizontal cross-sectional areas in the shape of a circle.

A major crystallographic orientation of each of the plurality of nanocones 40 can be aligned in the vertical direction, i.e., in the direction perpendicular to the base of that nanocone 40. In a non-limiting illustrative embodiment, the plurality of nanocones includes n-doped zinc oxide, and the (0001) crystallographic orientation of each of the plurality of nanocones 40 can be aligned in the vertical direction. In another non-limiting illustrative embodiment, the plurality of nanocones includes n-doped ZnₓCd₁₋ₓO, and the (0001) crystallographic orientation of each of the plurality of nanocones 40 can be aligned in the vertical direction.

In a demonstrative example of the structure of FIG. 3, a sample was prepared using a glass substrate as a transparent substrate layer 10, and a layer of indium tin oxide was employed as the transparent conductive oxide layer 20. An aluminum-doped ZnO (AZO) layer containing 2% of aluminum in weight percentage was deposited as a doped conductive oxide buffer layer 30 at about 500° C. On some samples, an in-house sputtering system was used with an ambient oxygen partial pressure of about 5 mTorr. This sputtering system was operated at 200 Watts power for 5 minutes. On some other samples, a pulsed laser deposition (PLD) system was employed. The thickness of the deposited aluminum-doped ZnO layer ranged from 50 nm to 200 nm. The aluminum-doped ZnO layer was used as a buffer layer for achieving vertical alignment of ZnO nanocones that were subsequently formed.

ZnO nanocones were successfully grown on the aluminum-doped ZnO layer using thermal vapor deposition at 600° C. that lasted for about 10 minutes under about 200 standard cubic centimeters per minute (sccm) flow of 5% oxygen gas (with 95% argon as the balance gas) at a reduced total pressure of about 1 Torr. The thermal vapor deposition system was incorporated within a three-temperature-zone furnace. Carbon powder was introduced upstream of the Zn source during thermal evaporation deposition so that carbon dioxide or carbon monoxide was provided as lateral growth control agent during the growth of the ZnO nanocones. The carbon dioxide or carbon monoxide provided the differential crystal growth rates between the interior of the terrace (top surface) and edge of the terrace of ZnO precursor islands during nucleation phase and also of the conductive oxide frustums after the nucleation phase.

Carbon dioxide or carbon monoxide was generated within the deposition chamber by placing carbon (graphite) powder upstream of the zinc source. The presence of the carbon enabled the formation of larger ZnO nucleation sites via a reaction between carbon dioxide or carbon monoxide and zinc. Once ZnO nucleation sites were formed during the nucleation phase, self-catalyzed formation of ZnO nanocones proceeded.

In the case of a small ZnO nucleation site (i.e., dimensions smaller than the migration length of adatoms), the catalytic growth rate is determined by the boundary facets of (10 1̅0) surfaces. In the case of a large ZnO nucleation site, the ZnO growth at the central sites is governed mainly by the high surface energy of the (0001) surface and is less influenced by the edge site, which includes the contributions from other low surface energy facets, such as {11 2̅0}, {10 1̅1}, and {10 1̅0} surfaces. In this case, the growth rate in the center site is faster than that near the edge site, leading to formation of the cone shape.

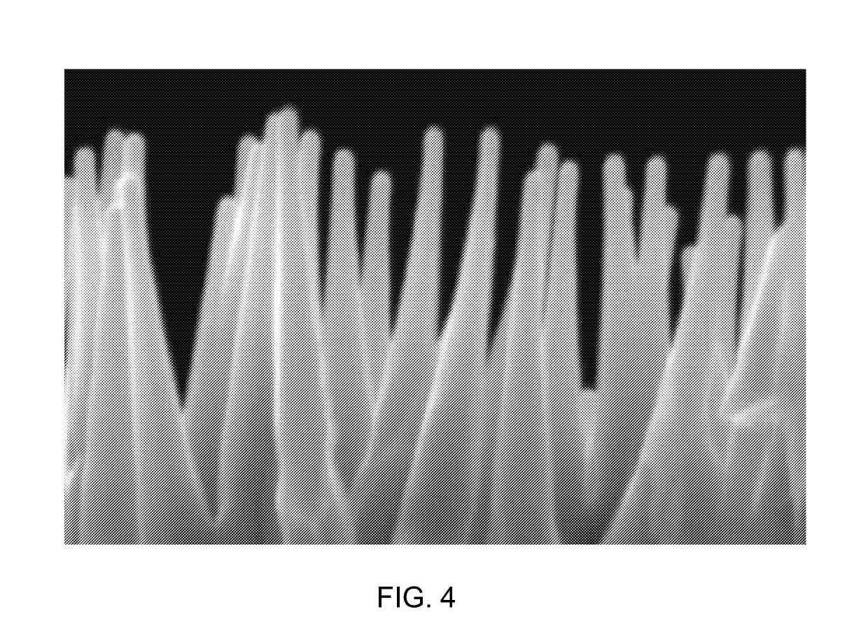

A scanning electron micrograph of one of the samples prepared by the above described method is shown in FIG. 4, which shows images of nanocones after the processing step of FIG. 3.

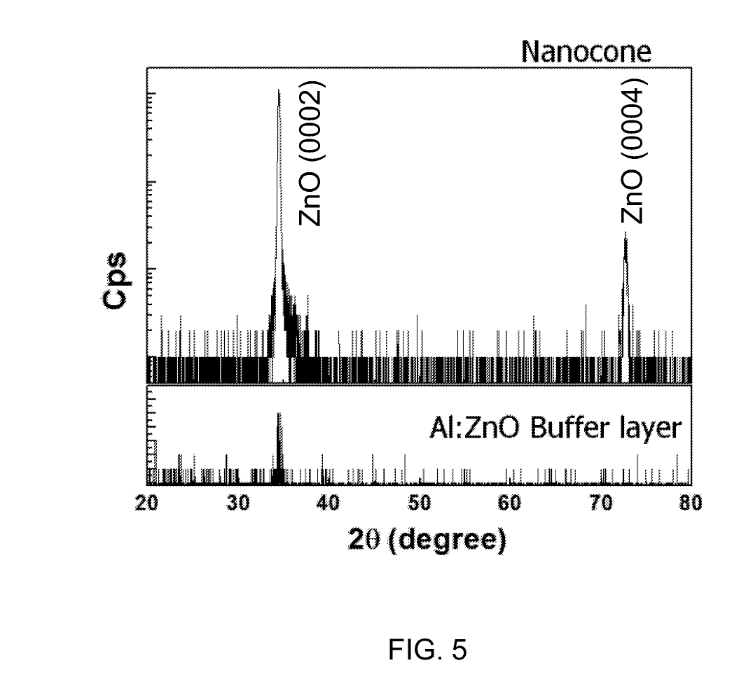

Referring to FIG. 5, an X-ray spectrum of an aluminum-doped zinc oxide buffer layer in one of the samples at the end of the processing step of FIG. 1 is shown in a lower portion. An X-ray spectrum of a sample including zinc oxide nanocones at the end of the processing step of FIG. 3 is shown in the upper portion. The two X-ray spectra confirm that the crystals of the an aluminum-doped zinc oxide buffer layer and the crystals of the plurality of ZnO nanocones 40 are aligned along the (0001) orientation, i.e., the (0001) crystallographic orientations of the materials of the aluminum-doped zinc oxide buffer layer and the crystals of the plurality of ZnO nanocones 40 are aligned along the direction perpendicular to the top surface of the aluminum-doped zinc oxide buffer layer.

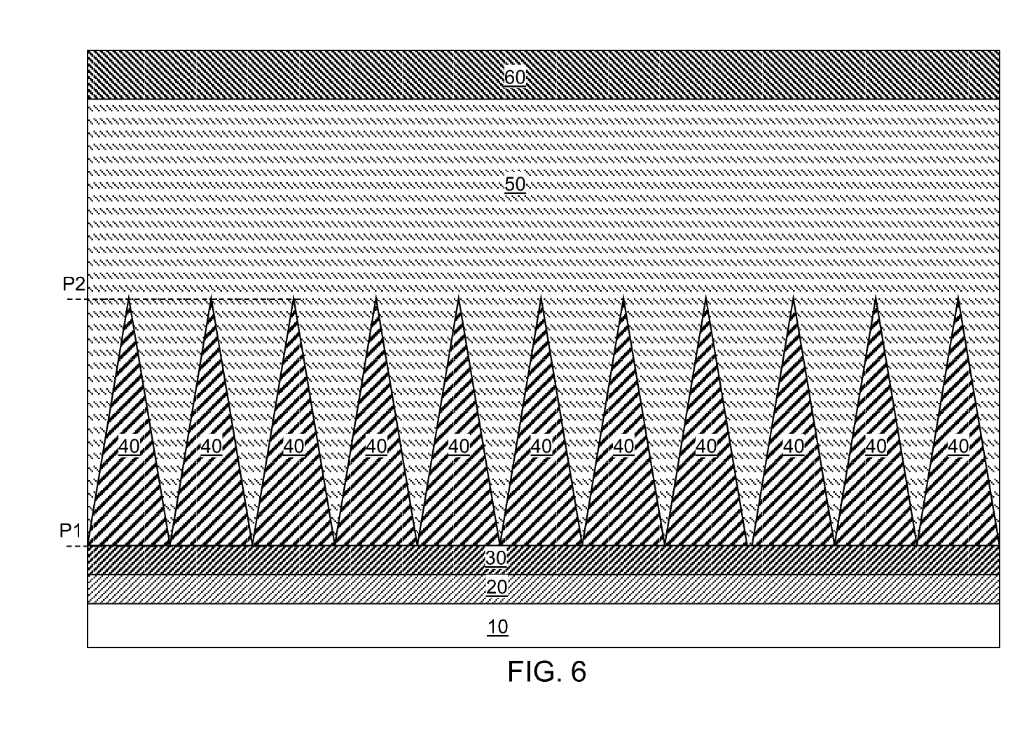

Referring to FIG. 6, the exemplary structure of FIG. 3 is further processed to form a doped semiconductor layer and a conductive plate 60 thereupon. The doped semiconductor layer is deposited with sufficient thickness so that the volume between the plurality of nanocones 40 is filled with the doped semiconductor layer. Thus, the doped semiconductor layer is a doped semiconductor matrix 50 that contacts, and embeds, the plurality of nanocones 40. By filling the space between the plurality of nanocones 40, the doped semiconductor matrix 50 embeds, i.e., completely laterally surrounds, the plurality of nanocones 40. The thickness of the doped semiconductor matrix 50, as measured from above the plurality of nanocones 40 to the topmost surface of the doped semiconductor matrix 50, can be from 1,000 nm to 10,000 nm, although lesser and greater thicknesses can also be employed.

The doped semiconductor matrix 50 has a doping of a second conductivity type, which is the opposite type of the first conductivity type. Thus, if the doped conductive oxide buffer layer 30 and the plurality of nanocones 40 have n-type doping, the doped semiconductor layer 50 has p-type doping, and vice versa. Thus, a three-dimensional p-n junction is formed across interfaces between the doped semiconductor matrix 50 and the plurality of nanocones 40. The three-dimensional p-n junction allows the exemplary structure of FIG. 6 to be used as a photovoltaic device. Specifically, the exemplary structure of FIG. 6 includes an “interdigitated” three-dimensional p-n junction because the upward-protruding portions of the plurality of nanocones 40 contact the recessed portions of the doped semiconductor matrix 50, and the downward-protruding portions of the doped semiconductor matrix 50 contact the sidewalls of the plurality of nanocones 40 that are recessed relative to the apexes of the plurality of nanocones 40. A large p-n junction area is provided in the exemplary structure of FIG. 6 compared with photovoltaic structures employing a planar junction structure and having a comparable device area. Specifically, ratio of the total p-n junction area of the exemplary device of FIG. 6 to the total p-n junction area of a planar device having the same device area is the same as the ratio of the total area of the side surfaces of the plurality of nanocones 40 to the total area of the bases of the plurality of nanocones 40.

Depletion regions are formed across the p-n junction as electrical charges permanently cross over the p-n junction until an electrostatic field is established to offset the diffusion of electrical charges across the p-n junction. Because of the limited lateral dimension of the nanocones 40, i.e., less than 5 microns, the entirety of the plurality of nanocones 40 can become a depleted region. Further, the entirety or at least an upper layer portion of the doped conductive oxide buffer layer 30 becomes depleted as well. Thus, a contiguous depletion region including all of the plurality of nanocones 40 and at least a portion of doped conductive oxide buffer layer 30 is formed below the interface between the plurality of nanocones 40 and the doped semiconductor matrix 50.

In addition, another depleted region extending upward from the interface between the plurality of nanocones 40 and the doped semiconductor matrix 50 is formed in a lower portion of the doped semiconductor matrix 50. This depletion region can extends at least between the first plane P1 including bases of the plurality of nanocones 40, i.e., the plane of the top surface of the doped conductive oxide buffer layer 30, and a second plane P2 that is parallel to the first plane and including an apex of the plurality of nanocones 40.

The directions of the axes of the nanocones 40 are predominantly aligned along the vertical direction, i.e., the direction perpendicular to the top surface of the doped conductive oxide buffer layer 30. The geometry of the nanocones 40 is more effective in providing electrical field components along the both longitudinal (i.e., axial) and lateral directions of the nanocones 40, and thus enhancing vertical movement of charge carriers generated by photons.

Thus, the photovoltaic device illustrated in FIG. 6 has a completely depleted junction region between the first plane P1 and the second plane P2, and the depletion region extends some distance above the second plane P2 and below the first plane P1. The depleted junction region produces an electric potential gradient inside the nanocone that greatly enhances the mobility of electrons in the nanocone, transverse toward the cone axis and longitudinally toward the base and charge collection electrode.

Specifically, modeling studies performed in the course of the present invention show that a nanocone-based junction is better for efficient carrier transport than a nanowire-based junction. Comparison of electrostatic fields in a nanocone-based heterojunction and in a nanowire-based heterojunction shows the calculated distributions of the electrostatic potentials for a nanocone p-n junction have a significant vertical component in the electrostatic field. In the modeled nanocone-based heterojunction, the base of a right angle nanocone having a cylindrical symmetry around the axis contacts a base conductive plate and the apex of the nanocone is the farthest point of the nanocone from the base conductive plate. In the modeled nanowire-based heterojunction, one end of a cylindrical nanowire contacts the top surface of the base conductive plate, and is perpendicular to the base plate. At the end of the calculation, the solutions of the Poisson equation for both nanocone-based and nanowire-based p-n structures were numerically obtained as a function of the shape, applied electric field, and carrier concentrations. Thus, the Poisson equation for the electrostatic potential takes the following form,

$${∇}^{2} φ = \frac{{V}_{th}}{{λ}_{D}^{2}} ( 1 - {e}^{- φ \text{/} {V}_{th}} ) , \qquad ( 1 )$$

where Vₜₕ=k_{B}T/q is the thermal voltage and λ_{D}=\sqrt{∈k_{B}T/q²N_{D}} is the Debye length, with T being the temperature, q the carrier charge, ∈ the dielectric constant of the medium, and N_{D} the dopant concentration. The Debye length is an important factor in determining the depletion region. As expected for the radial direction, the potential increases toward the center of the n-type core for both nanocone and nanowire structures.

The electrostatic potential decreases with increasing distance from a base conductive plate in the case of a nanocone, but not for the nanowire. Thus, a potential variation in a nanocone generates an electric field along the longitudinal direction, i.e., along the direction perpendicular to the plane of the base conductive plate and along the direction connecting the apex and the base of the nanocone. This field can increase the transport probability of electrons/holes and minimize their trapping in defects or via recombination routes. In contrast, in the nanowire, the movement of carriers depends on diffusion due to the constant electrostatic potential at the center, which likely decreases the carrier collection efficiency. The present invention thus employs a nanocone structure to provide an electrostatic field in the vertical direction and to minimize the recombination of charge carriers.

Thus, an electric potential gradient is present in each of the plurality of nanocones 40 in a direction perpendicular to bases of the plurality of nanocones 40. The electric potential gradient in a nanocone 40 includes a transverse component pointing toward an axis of the nanocone 40 and a longitudinal (i.e., axial) component pointing toward the base of that nanocone 40.

The potentials are varied throughout the entire CdTe film within 1 μm thickness, suggesting the layer is depleted. Electric fields, generated by the potentials, have both vertical components and lateral components. For lateral direction, a positive electric field toward a nearest nanocone tip exists in the whole space between nanocones 40. This is in contrast to electric fields present in planar junction devices, in which the electric field has only a vertical component but does not have any lateral component. The lateral electric field can drive minority carriers from the space between the nanocones 40 to the tip-film junction.

For the vertical direction, the vertical component of the electric field around the apexes of the nanocones 40 is much stronger than the corresponding vertical component of the electric field for a planar junction. For example, at 10 nm from an apex of a nanocone 40, the vertical electrical field of the exemplary structure can be about 4.35 V/μm, which is about two times the electrical field generated at a distance of 10 nm from a planar p-n junction. Such an increase in the vertical electrical field not only separates electrons and holes when they are generated by photons in the depleted CdTe, but also drives minority carriers (electrons) crossing from CdTe to ZnO nanocone much faster.

In a non-limiting illustrative embodiment, the plurality of nanocones 40 can include n-type ZnO or n-doped ZnₓCd₁₋ₓO in which x is greater than 0 and is less than 1, and the doped semiconductor matrix 50 can include p-type CdTe, p-type ZnTe, a combination thereof, or any p-type semiconductor material.

A conductive electrode layer 60 contacting the doped semiconductor matrix 50 is formed above the doped semiconductor matrix. The conductive electrode layer 60 can include any conductive material, transparent or opaque, and by any deposition method known in the art.

In a demonstrative example of the device illustrated in FIG. 6, various samples were fabricated. In some samples, the doped semiconductor matrix 50 was formed by depositing ZnTe on the surfaces of ZnO nanocones using pulsed laser deposition (PLD). A ZnTe target was mounted facing the ZnO nanocones so that the separation distance between the ZnTe target and the ZnO nanocones was about 6 cm. The substrate on which the ZnO nanocones had been grown was heated to 550° C. in vacuum. The ZnTe target was ablated using a pulsed KrF laser (λ=248 nm, 5 Hz pulse rate, 0.6˜1.5 J/cm² energy density) for 30,000 pulses to fully cover the ZnO nanocones with a ZnTe film. In these samples, the ZnTe layer was grown without intentional doping which results in a carrier concentration in the low 10¹⁵/cm³ for ZnTe.

In general, the dopant concentration in the doped semiconductor matrix 50 can be increased to a range from 10¹⁵/cm³ to 10¹⁸/cm³ in order to increase the efficiency of the photovoltaic device of the present invention. The p-type carrier concentration can be increased in the ZnTe layer, for example, by employing a high-density ZnTe target and/or by employing nitrogen ambient.

In another set of sample, a CdTe layer, which corresponds to the doped semiconductor matrix 50, was deposited on ZnO nanocones surface using thermal vapor deposition at 700° C. of source temperature and 400° C. of substrate temperature, i.e., the CdTe source material for evaporation was held at 700° C., and the ZnO nanocones were held at 400° C. A 6 micron thick CdTe film was obtained after 30 minutes of deposition. This thickness may be reduced to allow effective charge collection. After deposition of the CdTe layer, the p-n junction was thermally annealed at 400° C. for 30 minutes in air. As an alternative, CdCl₂ vapor treatment can be used for dopant activation in the CdTe film.

In an aspect of the present invention, at least one thermal pulse can be applied to the plurality of nanocones 40 and the doped semiconductor matrix 50. The method of applying at least one thermal pulse is herein referred to as pulse thermal processing (PTP). The thermal pulse can be provided by radiative heating that does not last more than 5 milliseconds, and typically lasts about 1 millisecond. Electrical characteristics of the interdigitated three-dimensional p-n junction can be enhanced in the photovoltaic structure including the plurality of nanocones 40 and the doped semiconductor matrix 50 by at least one of the two mechanisms. The at least one thermal pulse can be a single pulse, or can be a plurality of pulses.

The first mechanism is a decrease in interfacial defects between the doped semiconductor matrix 50 and the plurality of nanocones 40. The second mechanism is an increase in conductivity of the doped semiconductor matrix 50. For example, repetitive application of short-duration (on the order of a millisecond), high-energy thermal pulses on the photovoltaic structure including the plurality of nanocones 40 and the doped semiconductor matrix 50 can both improve the electronic contacts between the plurality of nanocones 40 and doped semiconductor matrix 50 and improve conductivity within the doped semiconductor matrix 50. The improvement in the electronic contacts is effected by reducing the interfacial defects between the doped semiconductor matrix 50 and the plurality of nanocones 40 during the application of the thermal pulses. The improvement in the conductivity of the doped semiconductor matrix 50 can be effected by increased activation of dopants and/or increase in the average grain size of the doped semiconductor matrix 50 that occurs as a consequence of an anneal due to the application of the at least one thermal pulse.

The simultaneous minimization of interfacial defects and the maximization of electrical conductivity improve charge separation and charge carrier mobility, leading to improvements in device efficiency. For example, in the case of a doped semiconductor matrix 50 including ZnTe deposited by pulsed layer deposition or CdTe deposited by thermal vapor deposition, both mechanisms contribute to enhance the electrical characteristics of the photovoltaic structure. Preferably, the temperature of ZnTe or CdTe during the pulse thermal processing does not exceed 700° C. for more than 50 milliseconds for each application of a thermal pulse.

The material for the conductive electrode layer 60 can be selected based on the material of the doped semiconductor matrix 50 in order to optimize the performance of the photovoltaic device. In an illustrative example, Ag can be employed for the conductive electrode layer 60 if CdTe is employed for the doped semiconductor layer 50. Cu can be employed for the conductive electrode layer 50 if ZnTe is employed for the doped semiconductor layer. Proper selection of the material for the conductive electrode layer 60 allows Ohmic contact between the conductive electrode layer 60 and the doped semiconductor matrix 50, thereby reducing Schottky effect.

While the structure in FIG. 6 illustrates an embodiment in which the doped semiconductor matrix 50 contacts all sidewall surfaces of the plurality of nanocones 40 and fully embeds the plurality of nanocones 40, variations in which the doped semiconductor matrix 50 does not contact all sidewall surfaces of the plurality of nanocones 40 and embeds the plurality of nanocones only partially can also be practiced.

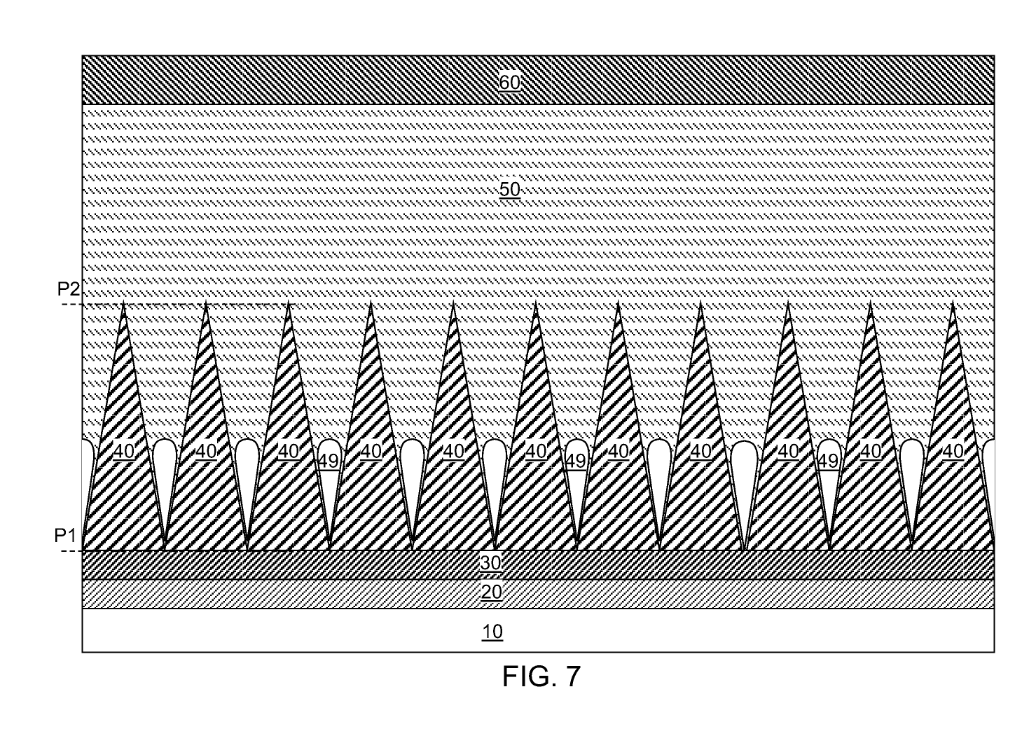

Referring to FIG. 7, a first variation of the exemplary structure can be formed by employing a non-conformal deposition process for the material of the doped semiconductor matrix 50. The non-conformal deposition process can be a depletive chemical vapor deposition (CVD) process in which deposition rate is limited by supply of reactants so that more material is deposited on the upper portions of the nanocones 40 than on the lower portions of the nanocones 40. Alternately, the non-conformal deposition process can be a physical vapor deposition (PVD) process, i.e., sputtering, in which the lower portions of the nanocones 40 are shadowed by upper portions of the nanocones 40 so that more material is deposited on the upper portions of the nanocones 40 than on the lower portions of the nanocones 40. Such differential in the deposition rate can lead to formation of cavities 49 between lower portions of nanocones 40, while the spaces between the upper portions of the nanocones 40 are completely filled by the doped semiconductor matrix 50. In some embodiments, the depletion of reactants or the shadowing effect can be so severe that the material of the doped semiconductor matrix 50 does not contact the lower portions of the nanocones 40.

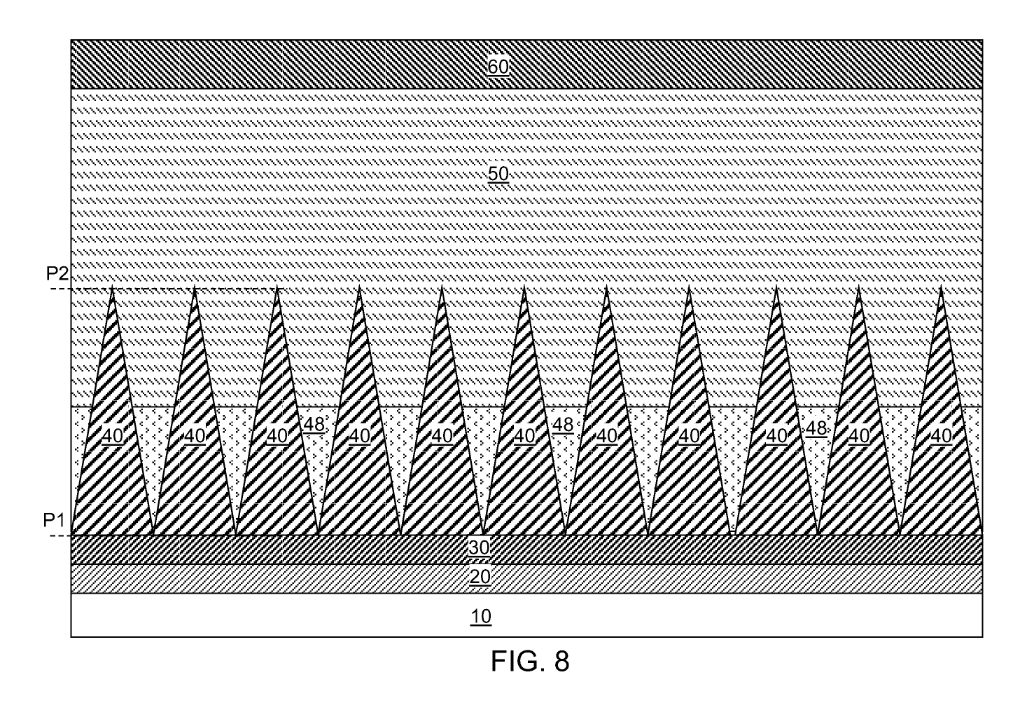

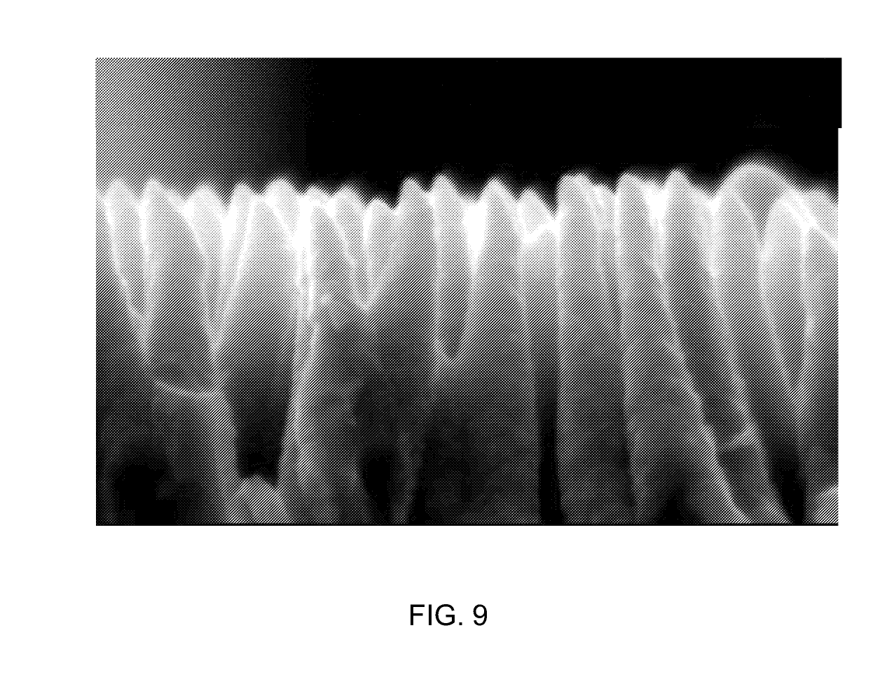

Referring to FIG. 8, a second variation of the exemplary structure can be derived from the exemplary structure of FIG. 3 by forming a transparent polymer layer 48 prior to formation of a doped semiconductor matrix 50. For example, the transparent polymer layer 40 can include a self-planarizing transparent polymer material that can be applied, for example, by spin coating. The transparent polymer layer 48 can include any transparent polymer material such as resin. The transparent polymer layer 48 is formed between the doped conductive oxide buffer layer 30 and the doped semiconductor matrix 50. The transparent polymer layer 48 can be advantageously employed for many purposes such as avoiding physical contact between the doped conductive oxide buffer layer 30 and the doped semiconductor matrix 50 in case the materials of the doped conductive oxide buffer layer 30 and the doped semiconductor matrix 50 can react upon contact to adversely affect the properties of the p-n junction. Another example of the purposes is to increase solar light transmittance into the doped semiconductor matrix 50, which functions as a light-absorber matrix.

Referring to FIG. 9, a scanning electron micrograph of a sample illustrates the initial coverage of ZnO nanocones with a thin layer of ZnTe that is deposited by pulsed laser deposition.

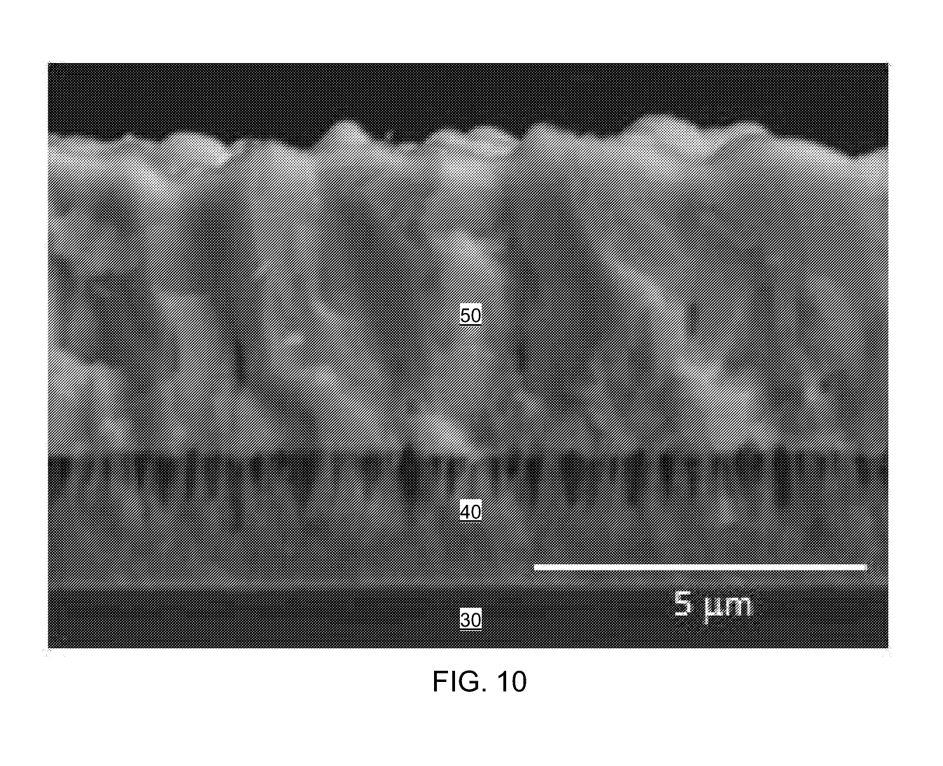

Referring to FIG. 10, a scanning electron micrograph (SEM) of a sample of a photovoltaic structure of FIG. 6 except a conductive electrode layer 60 is shown. A transparent substrate layer including silicate glass and a transparent oxide layer including indium tin oxide are not shown in the SEM. The doped conductive oxide buffer layer 30 includes aluminum in an aluminum-doped zinc oxide layer can be about 2% in weight percentage. The plurality of nanocones 40 are n-type ZnO nanocones. The doped semiconductor matrix 50 includes p-type CdTe.

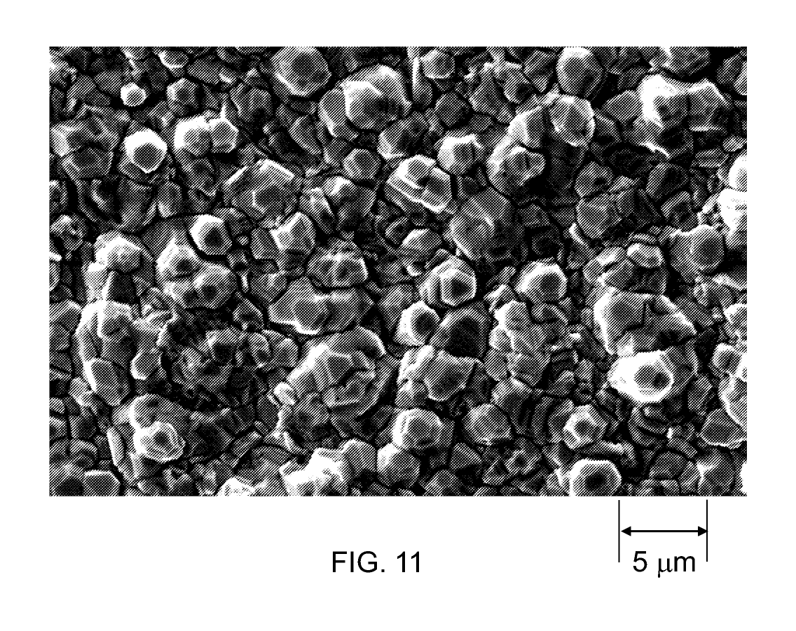

Referring to FIG. 11, a scanning electron micrograph of a surface of the CdTe layer of the sample of FIG. 10 shows that the deposited CdTe layer has a large average grain size that is greater than 1 micron in diameter.

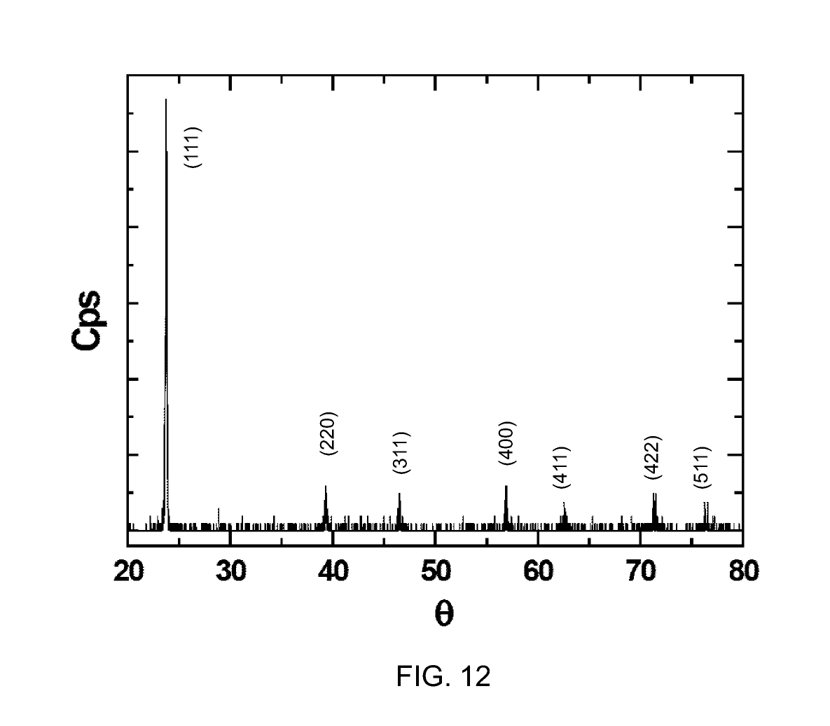

FIG. 12 shows an X-ray spectrum of the CdTe layer of FIG. 10. This X-ray spectrum shows that the CdTe layer is stoichiometric, i.e., ratio of the number of Cd atoms to the number of Te atoms is 1:1. Further, most crystallographic orientations of the grains in the CdTe layer are along major crystallographic orientations in which the Miller indices do not exceed 6 in absolute value.

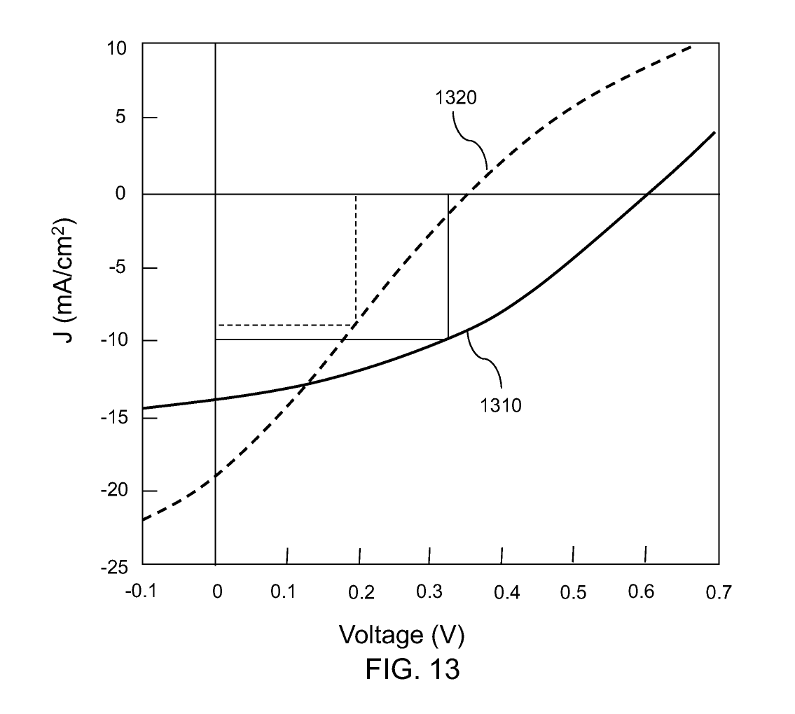

Referring to FIG. 13, a J-V plot compares the performance of an exemplary nanocone ZnO—CdTe solar cell according to an embodiment of the present disclosure and the performance of a reference ZnO—CdTe solar cell having planar layers. The J-V curve of the exemplary nanocone ZnO—CdTe solar cell is shown as a first curve 1310, and the J-V curve of the reference ZnOP—CdTe solar cell having planar layers is shown as a second curve 1320. The first curve 1310 provides an efficiency of 3.2% at a power-maximizing point of the first curve 1310 marked with a corner of a solid rectangle. The second curve 1320 provides an efficiency of 1.8% at a power-maximizing point of the second curve 1320 marked with a corner of a dotted rectangle. Thus, the three-dimensional geometry of the nanocones 40 provides an improvement in the efficiency of the solar cell by a factor of about 78%.

While the invention has been described in terms of specific embodiments, it is evident in view of the foregoing description that numerous alternatives, modifications and variations will be apparent to those skilled in the art. Accordingly, the invention is intended to encompass all such alternatives, modifications and variations which fall within the scope and spirit of the invention and the following claims.

What is claimed is:

1. A photovoltaic device comprising a p-n junction between a plurality of nanocones having a doping of a first conductivity type, and a doped semiconductor matrix contacting and at least partially embedding said plurality of nanocones and having a doping of a second conductivity type that is the opposite of the first conductivity type.

2. The photovoltaic device of claim 1, wherein an entirety of said plurality of nanocones is a depleted region.

3. The photovoltaic device of claim 2, wherein said doped semiconductor matrix includes another depleted region extending at least between a first plane including bases of said plurality of nanocones and a second plane that is parallel to said first plane and including an apex of said plurality of nanocones.

4. The photovoltaic device of claim 1, wherein an electric potential gradient is present in each of said plurality of nanocones in a direction perpendicular to bases of said plurality of nanocones.

5. The photovoltaic device of claim 4, wherein said electric potential gradient in a nanocone includes a transverse component pointing toward an axis of said nanocone and a longitudinal component pointing toward a base of said nanocone.

6. The photovoltaic device of claim 1, wherein an electric potential gradient is present in said doped semiconductor matrix in both a vertical direction and horizontal directions.

7. The photovoltaic device of claim 1, further comprising a doped conductive oxide buffer layer contacting bases of said plurality of nanocones and having a doping of said first conductivity type and comprising aluminum-doped zinc oxide.

8. The photovoltaic device of claim 1, wherein said plurality of nanocones comprises n-type ZnO or n-type ZnₓCd₁₋ₓO in which x is greater than 0.8 and is less than 1.

9. The photovoltaic device of claim 8, wherein said doped semiconductor matrix comprises CdTe, ZnTe, or another p-type semiconductor material.

10. The photovoltaic device of claim 1, wherein each of said plurality of nanocones has a height from 250 nm to 1,000 nm.

11. The photovoltaic device of claim 1, wherein a crystallographic orientation of each of said plurality of nanocones is aligned in a direction perpendicular to a base of that nanocone.

12. The photovoltaic device of claim 14, wherein a (0001) crystallographic orientation of each of said plurality of nanocones is aligned in a direction perpendicular to said base of said nanocone.

13. A method of forming a photovoltaic device comprising:
forming a plurality of nanocones having a doping of a first conductivity type on a transparent conductive oxide (TCO) substrate; and
forming a doped semiconductor matrix having a doping of a second conductivity type that is the opposite of the first conductivity type directly on said plurality of nanocones, wherein said plurality of nanocones become at least partially embedded in said doped semiconductor matrix, and a p-n junction is formed between said plurality of nanocones and said doped semiconductor matrix.

14. The method of claim 13, wherein said plurality of nanocones is formed directly on a surface of a doped conductive oxide buffer layer that is provided within said TCO substrate.

15. The method of claim 13, wherein said plurality of nanocones is grown by a vertical growth of a plurality of frustums.

16. The method of claim 15, wherein each of said plurality of frustums has a terrace at top, wherein crystal growth rate of a material of said plurality of frustums is different between growth on said terrace and growth at edges at a periphery of said terrace.

17. The method of claim 13, wherein growth of said plurality of frustums proceeds by deposition on said terrace and said material is not deposited on said side surfaces.

18. The method of claim 13, wherein said plurality of nanocones is grown in an ambient including a lateral growth control agent.

19. The method of claim 13, wherein said lateral growth control agent is carbon dioxide or carbon monoxide.

20. The method of claim 13, wherein an entirety of said plurality of nanocones becomes a depleted region upon formation of said doped semiconductor matrix.

21. The method of claim 20, wherein said doped semiconductor matrix includes another depleted region extending at least between a first plane including bases of said plurality of nanocones and a second plane that is parallel to said first plane and including an apex of said plurality of nanocones.

22. The method of claim 13, further comprising applying a thermal pulse to said doped semiconductor matrix, wherein interfacial defects between said doped semiconductor matrix and said plurality of nanocones are reduced by application of said thermal pulse.

23. The method of claim 13, wherein said plurality of nanocones comprises n-type ZnO or n-type ZnₓCd₁₋ₓO in which x is greater than 0.8 and is less than 1.

24. The method of claim 23, wherein said doped semiconductor matrix comprises CdTe, ZnTe, or a combination thereof.

25. A method of enhancing charge transport characteristics of an interdigitated three-dimensional p-n junction, said method comprising:
forming a plurality of nanocones having a doping of a first conductivity type on a transparent conductive oxide (TCO) substrate;
forming a doped semiconductor matrix directly on said plurality of nanocones, wherein said doped semiconductor matrix has a doping of a second conductivity type that is the opposite of the first conductivity type, wherein an interdigitated three-dimensional p-n junction is formed between an interface between said doped semiconductor matrix and said plurality of nanocones; and
applying at least one thermal pulse to said plurality of nanocones and said doped semiconductor matrix, wherein electrical characteristics of said interdigitated three-dimensional p-n junction include at least one of a decrease in interfacial defects between said doped semiconductor matrix and said plurality of nanocones and an increase in conductivity of said doped semiconductor matrix.

26. The method of claim 25, wherein each of said at least one thermal pulse is applied for a duration not longer than 5 milliseconds.

27. The method of claim 25, wherein said at least one thermal pulse is a plurality of thermal pulses.

28. The method of claim 25, wherein said plurality of nanocones comprises n-type ZnO or n-type ZnₓCd₁₋ₓO in which x is greater than 0 and is less than 1, and said doped semiconductor matrix comprises CdTe, ZnTe, or a combination thereof.

29. The method claim 25, wherein an average grain size of said doped semiconductor matrix increases after application of said at least one thermal pulse.
